(19) United States
(12) Patent Application Publication
(10) Pub. No.: US 2019/0059145 A1
(43) Pub. Date: Feb. 21, 2019

(54) METHOD FOR TESTING LED BACKLIGHT

(71) Applicant: SHARP KABUSHIKI KAISHA, Sakai City, Osaka (JP)

(72) Inventor: RYUHICHI MIYOSHI, Sakai City (JP)

(21) Appl. No.: 15/764,610

(22) PCT Filed: Nov. 22, 2016
(86) PCT No.: PCT/JP2016/084540

§ 371 Date: Mar. 29, 2018

(30) Foreign Application Priority Data
Nov. 30, 2015 (JP) 2015-232682

(51) Int. Cl. H05B 37/03; H05B 33/08; G02F 1/13; G01R 31/44

(52) U.S. Cl. CPC H05B 37/036; G01R 31/44; G02F 1/1309; H05B 33/089

(57) ABSTRACT

An LED backlight (15) having a plurality of LED groups (19) each including a plurality of LEDs (17) connected in series is tested. The LED groups (19a to 19c) are driven with a constant current respectively, and operating voltages (Vf1 to Vf3) of the LED groups (19a to 19c) are measured respectively. The LED backlight (15) is determined as normal when all of differences between the operating voltages (Vf1 to Vf3) are less than a reference value, and is determined as abnormal otherwise. With this, an open circuit failure and a short circuit failure of the LED (17) can be detected. A leakage failure of the LED (17) may be detected by switching an amount of a drive current used for driving with the constant current, to a minute current. Thus, the LED backlight is tested certainly and easily.

### TECHNICAL FIELD

The present invention relates to a method for testing a backlight provided in a display device, and more particularly to a method for testing an LED backlight including a plurality of LEDs.

### BACKGROUND ART

In a non-light emission type display device, such as a liquid crystal display device, a backlight for irradiating a back surface of a display panel with light is provided. The backlight is configured using, for example, a plurality of LEDs (light emitting diodes) and a light guide plate. Hereinafter, a method for testing an LED backlight including the plurality of LEDs will be discussed.

In a manufacturing process of the liquid crystal display device, the backlight is tested. Generally, the backlight is tested by writing a video signal for white display to a liquid crystal panel, turning on the backlight at a predetermined luminance, and measuring a luminance of a display screen at that time. There is also known a method for measuring a voltage or a current in a backlight drive circuit when the backlight turns on.

In relation to the present invention, Patent Document 1 discloses a method for determining that a display failure does not occur in the liquid crystal display device to be tested when a difference between a luminance level applied to the backlight of the liquid crystal display device in which the display failure does not occur and the luminance level applied to the backlight of the liquid crystal display device to be tested is small. Patent Document 2 discloses a method for generating an LED short signal for an LED group including the plurality of LEDs connected in series, by comparing a voltage of a certain node in the LED group and a voltage obtained by dividing an end-to-end voltage of the LED group.

### PRIOR ART DOCUMENTS

### Patent Documents

Patent Document 1 Japanese Laid-Open Patent Publication. No. 2011-158684

Patent Document 2 Japanese Laid-Open Patent Publication No. 2012-160436

### SUMMARY OF THE INVENTION

### Problems to be Solved by the Invention

In testing the LED backlight, an LED which does not turn on due to an open circuit failure or a short circuit failure, an LED which turns on only at a low luminance due to a leakage failure, and the like are detected. However, in conventional methods for testing by measuring the luminance of the display screen, such an abnormal LED can not be detected, and the LED may not turn on at a desired luminance after shipment of the liquid crystal display device.

FIG. 14 is a diagram showing a turn-on state of an LED backlight. In the LED backlight shown in FIG. 14, a plurality of LEDs (dot pattern portions) 91 are arranged along one side of a light wide late 92. Arrows shown in FIG. 14 shows how light emitted from the LEDs 91 propagates inside the light guide plate 92. In a normal backlight (FIG. 14 (a)) all of the LEDs 91 turn on, whereas an abnormal backlight (FIG. 14 (b)) includes an LED 93 (black painted portion) which does not turn on. Thus, there is a difference in the luminance of the display screen between the normal backlight and the abnormal backlight.

However, as a number of LEDs included in the backlight increases, a ratio occupied by luminance caused by turn-on of one LED in the luminance of the display screen decreases. Thus, even if there exists an LED that does not turn on, the luminance of the display screen may change only within a range of a luminance variation amount when all the of LEDs turn on. In this case, even if the luminance of the disc lay screen is measured, it is not possible to detect an existence of the LED that does not turn on.

Furthermore, in the conventional methods for testing by measuring the voltage or the current in the backlight drive circuit, there is a problem that implementation is difficult or a cost is expensive if it is implemented, because it is necessary to add test terminals

Accordingly, an object of the present invention is to provide a method for testing an LED backlight certainly and easily.

### Means for Solving the Problems

According to a first aspect of the present invention, there is provided a method for testing an LED backlight provided in a display device and having a plurality of LED groups each including a plurality of LEDs connected in series, the method including steps of: driving the LED groups with a constant current respectively; measuring operating voltages of the LED groups respectively; and determining that the LED backlight is normal when all of differences between the operating voltages are less than a reference value and determining that the LED backlight is abnormal otherwise.

According to a second aspect of the present invention, in the first aspect of the present invention, the plurality of LEDs included in the LED group are connected in series so that a cathode terminal of the LED in a previous stage is connected to an anode terminal of the LED in a next stage.

According to a third aspect of the present invention, in the second aspect of the present invention, the anode terminal of the LED in a first stage included in the LED group is connected to a first terminal common to all of the LED groups, the cathode terminal of the LED in a last stage included in the LED group is connected to a second terminal provided for each LED group, and in driving with the constant current, a test potential is applied to the first terminal and potential in accordance with a current flowing through the LED group is applied to the second terminal.

According to a fourth aspect of the present invention, in the third aspect of the present invention, in determining, whether all of the differences between the operating voltages are less than the reference value is determined by determining whether a difference between a maximum value and a minimum value of the operating voltages is less than the reference value.

According to a fifth aspect of the present invention, in the first aspect of the present invention, the display device is placed in a constant temperature chamber whose inside is in a high temperature state.

According to a sixth aspect of the present invention, in the first aspect of the present invention, the method for testing further includes a step of switching an amount of a drive current used in driving with the constant current, between a normal current and a minute current.

According to a seventh aspect of the present invention, in the first aspect of the present invention, the display device has the LED backlight and a liquid crystal panel.

According to an eighth aspect of the present invention, in the seventh aspect of the present invention, the LED backlight has a configuration in which the plurality of LEDs are arranged along one or more sides of a light guide plate.

According to a ninth aspect of the present invention, there is provided a test apparatus for an LED backlight provided in a display device and having a plurality of LED groups each including a plurality of LEDs connected in series, the apparatus including: a constant current control unit configured to drive the LED groups with a constant current respectively; a voltage measurement unit configured to measure operating voltages of the LED groups respectively; and a determination unit configured to determine that the LED backlight is normal when all of differences between the operating voltages are less than a reference value and determine that the LED backlight is abnormal otherwise.

### Effects of the Invention

According to the first, second or ninth aspect of the present invention, the LED backlight can be tested certainly by measuring the operating voltages of the LED groups respectively and determining whether the LED backlight is normal based on the differences between the operating voltages of the LED groups. Furthermore, since the LED backlight is tested using existing terminals provided for driving the LED groups, the LED backlight can be tested easily without adding test terminals to the LED groups.

According to the third aspect of the present invention, the LED backlight having anode-side terminals of the LED groups connected to the same terminal can be tested certainly and easily.

According to the fourth aspect of the present invention, whether all of the differences between the operating voltages are less than the reference value can be determined easily by comparing the difference between the maximum value and the minimum value of the operating voltages with the reference value.

According to the fifth aspect of the present invention, it is possible to detect a loose contact failure of a wire bond wiring, which is difficult to detect at room temperature, by testing the LED backlight in the high temperature state.

According to the sixth aspect of the present invention, it is possible to detect a leakage failure of the LED, which can not be detected even when the LED group is driven with the constant current using the normal current, by driving the LED group with the constant current using the minute current.

According to the seventh aspect of the present invention, the LED backlight provided in the liquid crystal display device can be tested certainly and easily.

According to the eighth aspect of the present invention, the LED backlight including the plurality of LEDs and the light guide date can be tested certainly and easily.

### BRIEF DESCRIPTION OF THE DRAWINGS

FIG. 1 is a block diagram showing a configuration of a liquid crystal display device to be tested.

FIG. 2 is a diagram showing a physical configuration of an LED backlight of the liquid crystal display device shown in FIG. 1.

FIG. 3 is a diagram showing electrical configuration of the LED backlighting of the liquid crystal display device shown in FIG. 1.

FIG. 4 is a diagram explaining a method for testing according to a first embodiment of the present invention.

FIG. 5 is a diagram for explaining the method for testing the LED backlight according to the first embodiment.

FIG. 6 is a circuit diagram showing a part of a constant current control unit of a test apparatus shown in FIG. 5.

FIG. 7 is a flowchart showing the method for testing the LED backlight according to the first embodiment.

FIG. 8 is a diagram showing differences between operating voltages of LED groups.

FIG. 9 is a diagram for explaining a method for testing according to a second embodiment of the present invention.

FIG. 10 is a diagram for explaining a method for testing according to a third embodiment of the present invention.

FIG. 11 is a diagram for explaining the method for testing the LED backlight according to the third embodiment.

FIG. 12 is a circuit diagram showing a part of a constant current control unit and a current switching unit of a test apparatus shown in FIG. 11.

FIG. 13 is a diagram showing the differences between the operating voltages of the LED groups.

FIG. 14 is a diagram showing a turn-on state of an LED backlight.

### MODES FOR CARRYING OUT THE INVENTION

Hereinafter, methods for testing an LED backlight according to embodiments of the present invention will be described with reference to the drawings. The method for testing according to each embodiment of the present invention is a method for testing the LED backlight provided in a non-light emission type display device. The LED backlight has a plurality of LED groups each including a plurality of LEDs connected in series. Hereinafter, methods for testing the LED backlight provided in a liquid crystal display device will be described.

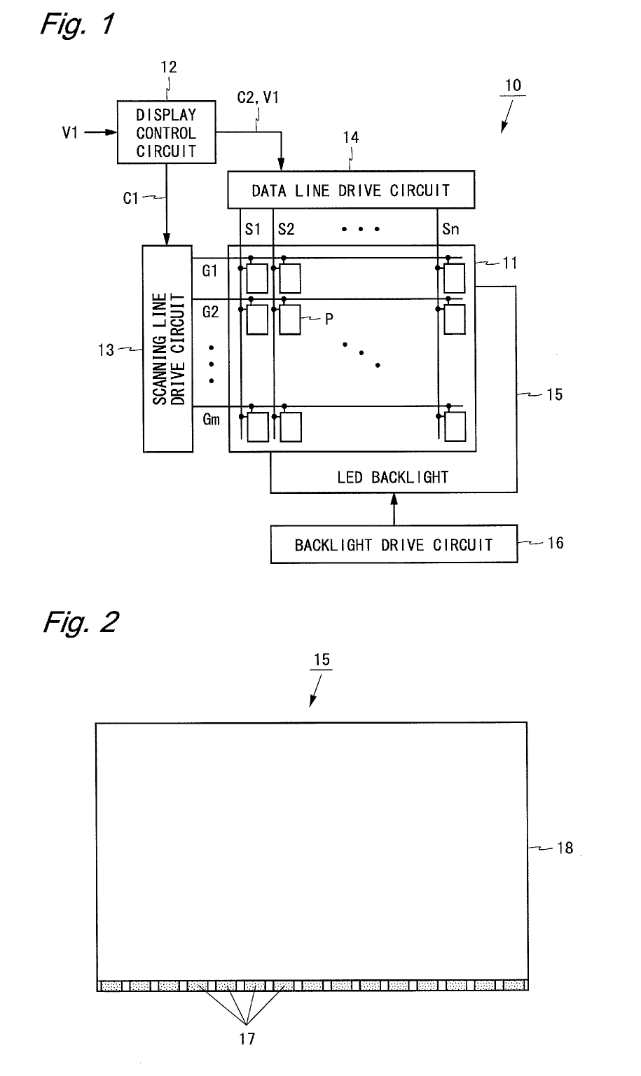

FIG. 1 is a block diagram showing a configuration of a liquid crystal display device to be tested. A liquid crystal display device 10 shown in FIG. 1 includes a liquid crystal panel 11, a display control circuit 12, a scanning line drive circuit 13, a data line drive circuit 14, an LED backlight 15, and a backlight drive circuit 16. Hereinafter, it is assumed that m, n, p and q are integers not smaller than 2.

The liquid crystal panel 11 includes m scanning lines G1 to Gm, n data lines S1 to Sn, and (m×n) pixel circuits P. The scanning lines G1 to Gm are arranged in parallel with each other. The data lines S1 to Sn are arranged in parallel with each other so as to intersect with the scanning lines G1 to Gm perpendicularly. The scanning lines G1 to Gm and the data lines S1 to Sn intersect at (m×n) positions. The (m×n) pixel circuits P are arranged corresponding to (m×n) intersections.

The display control circuit 12 outputs a control signal C1 to the scanning line drive circuit 13, and outputs a control signal C2 and a video signal V1 to the data line drive circuit 14. Based on the control signal C1, the scanning line drive circuit 13 sequentially selects one scanning line from among the scanning lines G1 to Gm and applies a write voltage (voltage with which a write control transistor (not shown) in the pixel. circuit P turns on) to the selected scanning signal line. With this, n pixel circuits P connected to the selected scanning line are selected. Based on the control signal C2, the data line drive circuit 14 applies, to the data lines S1 to Sn, n voltages in accordance with the video signal V1. With this, the n voltages are written to the n selected pixel circuits P, respectively.

The LED backlight 15 is disposed on a back side of the liquid crystal panel 11, and irradiates a back surface of the liquid crystal panel 11 with light. The backlight drive circuit 16 drives the LED backlight 15. More specifically, the backlight drive circuit 16 drives a plurality of LEDs included in the LED backlight 15 with a constant current.

FIG. 2 is a diagram showing a physical configuration of the LED backlight 15. The LED backlight 15 shown in FIG. 2 includes a plurality of LEDs 17 and a light guide plate 18. The plurality of LEDs 17 are arranged along one side (lower side in FIG. 2) of the light guide plate 18. In place of the arrangement shown in FIG. 2, the plurality of LEDs 17 may be arranged along two opposing sides (for example, an upper side and a lower side) of the light guide plate 18, or the plurality of LEDs 17 may be arranged two-dimensionally.

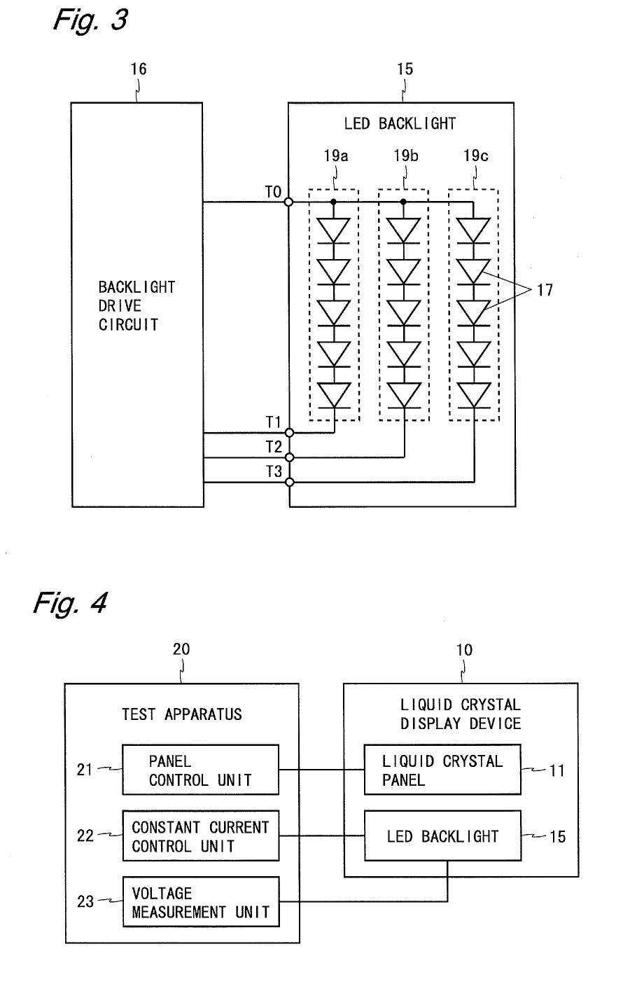

FIG. 3 is a diagram showing an electrical configuration of the LED backlight 15. As shown in FIG. 3, the plurality of LEDs 17 included in the LED backlight 15 are classified into a plurality of LED groups 19 each including a plurality of LEDs 17. The plurality of LEDs 17 included in each LED group 19 are connected in series so that a cathode terminal of the LED 17 in a previous stage is connected to an anode terminal of the LED 17 in a next stage. In general, when the LED backlight includes (p×q) LEDs, the (p×q) LEDs are classified into p groups each including q LEDs, and the q LEDs included in each LED group are connected in series.

FIG. 3 describes the LED backlight 15 in a case where p=3 and q=5. In the LED backlight 15 shown in FIG. 3, fifteen LEDs 17 are classified into three LED groups 19a to 19c each including five LEDs 17. The five LEDs 17 included in the LED group 19a are connected in series. The same holds true for the LED groups 19b, 19c. The LED backlight 15 has four terminals T0 to T4 in order to connect with the backlight drive circuit 16. The anode terminals of the LEDs 17 in a first stage included in the LED groups 19a to 19c are connected to the terminal T0 common to the LED groups 19a to 19c. The cathode terminals of the LEDs 17 in a last stage included in the LED groups 19a to 19c are connected to the terminals T1 to T3 provided for each of the LED groups 19a to 19c, respectively.

The backlight drive circuit 16 drives the plurality of LEDs 17 included in the LED backlight 15 with the constant current. More specifically, the backlight drive circuit 16 applies, between the terminals T0, T1, a voltage for making a drive current for light emission flow to the LED group 19a. For this purpose, the backlight drive circuit 16 applies a fixed potential to the terminal T0 and applies, to the terminal T1, a potential in accordance with a current flowing from the terminal T1 (current flowing through the LED group 19a). Furthermore, the backlight drive circuit 16 applies, to the terminal T2, a potential in accordance with a current flowing from the terminal T2 (current flowing through the LED group 19b) in order to make a drive current having the same amount flow to the LED group 19b, and applies, to the terminal T3, a potential in accordance with a current flowing from the terminal T3 (current flowing through the LED group 19c) in order to make a drive current having the same amount flow to the LED group 19c.

### First Embodiment

FIG. 4 is a diagram for explaining a method for testing according to a first embodiment of the present invention. As shown in FIG. 4, the liquid crystal display device 10 is tested using a test apparatus 20 including a panel control unit 21, a constant current control unit 22, and a voltage measurement unit 23. The panel control unit 21 is provided for testing the liquid crystal panel 11. The panel control unit 21 writes a video signal for test to the liquid crystal panel 11. It is possible to check whether the liquid crystal panel 11 is normal or abnormal by visually confirming display screen at that time by an operator (or by matching the display screen obtained automatically with a correct screen by the test apparatus 20).

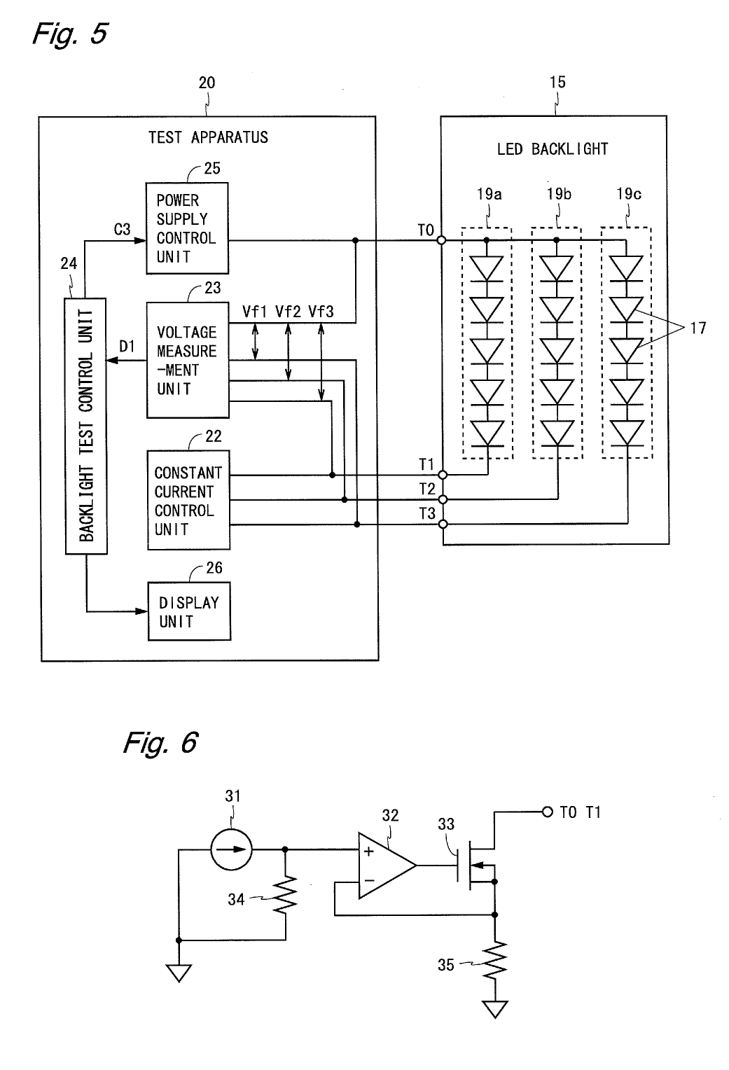

Hereinafter, a method for testing the LED backlight 15 using the constant current control unit 22 and the voltage measurement unit 23 will be described. FIG. 5 is a diagram for explaining the method for testing the LED backlight according to the present embodiment. In FIG. 5, among constituent elements of the test apparatus 20, elements related to testing the LED backlight 15 are described. As shown in FIG. 5, the test apparatus 20 includes the constant current control unit 22, the voltage measurement unit 23, a backlight test control unit 24, a power supply control unit 25, and a display unit 26.

The backlight test control unit 24 outputs, to the power supply control unit 25, a control signal C3 indicating whether to supply a test voltage to the LED backlight 15. An output terminal of the power supply control unit 25 is connected to the terminal T0 of the LED backlight 15. Based on the control signal C3, the power supply control unit 25 switches whether to apply a test potential to the terminal T0.

The constant current control unit 22 is connected to the terminals T1 to T3 of the LED backlight 15. The constant current control unit 22 applies, to the terminal T1, a potential in accordance with the current flowing from the terminal T1 in order to make a normal current for test flow to the LED group 19a. Similarly, the constant current control unit 22 applies, to the terminal T2, a potential in accordance with the current flowing from the terminal T2 in order to supply a normal current having the sonic amount to the LED group 19b, and applies, to the terminal T3, a potential in accordance with the current flowing from the terminal T3 in order to supply a normal current having the same amount to the LED group 19c.

FIG. 6 is a circuit diagram showing a part of the constant current control unit 22. FIG. 6 describes a circuit corresponding to the LED group 19a. The circuit shown in FIG. 6 includes a constant current source 31, an operational amplifier 32, an N-channel type MOSFET (Metal Oxide Semiconductor Field Effect Transistor) 33, and resistors 34, 35. One end of the constant current source 31 and one end of the resistor 34 are connected to a non-inverting input terminal of the operational amplifier 32. A drain terminal of the MOSFET 33 is connected to the terminal T1 of the LED backlight 15. A source terminal of the MOSFET 33 is connected to an inverting input terminal of the operational amplifier 32 and one end of the resistor 35. An output terminal of the operational amplifier 32 is connected to a gate terminal of the MOSFET 33. The other end of the constant current source 31 and the other ends of the resistors 34, 35 are grounded. Corresponding to the LED groups 19b, 19c, the constant current control unit 22 includes circuits having the same configuration as the circuit shown in FIG. 6.

In the circuit shown in FIG. 6, a gate potential of the MOSFET 33 changes in accordance with difference between an amount of a current flowing from the constant current source 31 and an amount of a current flowing through the MOSFET 33 (an amount of the current flowing through the LED group 19a). The amount of the current flowing through the MOSFET 33 changes in accordance with a gate-source voltage of the MOSFET 33. Therefore, by using the circuit shown in FIG. 6, the amount of the current flowing through the LED group 19a can be made equal to the amount of the current flowing from the constant current source 31. Similarly, an amount of the current flowing through the LED group 19b and an amount of the current flowing through the LED group 19c can be made equal to the amount of the current flowing from the constant current source 31.

The voltage measurement unit 23 is connected to the terminals T0 to T3 of the LED backlight 15 and measures operating voltages Vf1 to Vf3 of the LED groups 19a to 19c. More specifically, the voltage measurement unit 23 measures a voltage between the terminals T0, T1 as the operating voltage Vf1 of the LED group 19a, measures a voltage between the terminals T0, T2 as the operating voltage Vf2 of the LED group 19b, and measures a voltage between the terminals T0, T3 as the operating voltage Vf3 of the LED group 19c. The voltage measurement unit 23 outputs, to the backlight test control unit 24, measurement data D1 including the measured operating voltages Vf1 to Vf3.

In the test apparatus 20, a reference value (limit value) Vdlim1 of a difference between the operating voltages of the LED groups 19 is determined in advance. Based on the measurement data D1, the back test control unit 24 determines that the LED backlight 15 is normal when all of the differences between the operating voltages are less than the reference value Vdlim1, and determines that the LED backlight 15 is abnormal otherwise (when any of the differences between the operating voltages is not less than the reference value Vdlim1). More specifically, the backlight test control unit 24 obtains a maximum value and a minimum value of the operating voltages, and determines that the LED backlight 15 is normal when a difference between the maximum value and the minimum value of the operating voltages is less than the reference value Vdlim1, and determines that the LED backlight 15 is abnormal otherwise (when the difference between the maximum value and the minimum value of the operating voltages is not less than the reference value Vdlim1).

In a case where p=3, three operating voltages Vf1 to Vf3 are input to the backlight test control unit 24. In this case, the backlight test control unit 24 obtains a maximum value Vfmax and a minimum value Vfmin of the operating voltages Vf1 to Vf3, determines that the LED backlight 15 is normal when Vfmax−Vfmin<Vdlim1 is satisfied, and determines that the LED backlight 15 is abnormal when Vfmax−Vfmin≥Vdlim1 is satisfied. As described above, the backlight test control unit 24 determines whether all of the differences between the operating voltages Vf1 to Vf3 are less than the value Vdlim1 by determining whether the difference between the maximum value Vfmax and the minimum value Vfmin of the operating voltages Vf1 to Vf3 is less than the reference value Vdlim1. With this, whether all of the differences between the operating voltages are less than the reference value Vdlim1 can be determined easily.

The display unit 26 displays a screen showing a determination result by the backlight rest control unit 24. The display unit 26 may display only whether the LED backlight 15 is normal or abnormal, may display which of the LED groups 19 includes the abnormal LED 17, or may display a type of an abnormality occurred in the LED 17 (open circuit failure or short circuit failure). It is possible for the operator to know a test result of the LED backlight 15 by watching the screen displayed on the display unit 26.

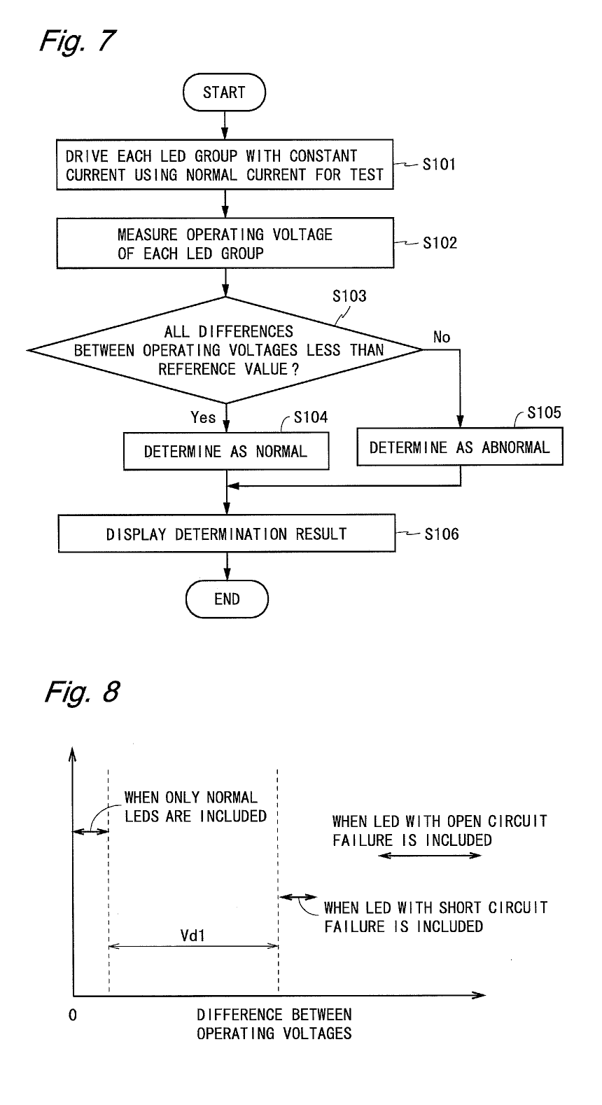

A flowchart of the above-described method for testing the LED backlight is shown in FIG. 7. As shown in FIG. 7, the test apparatus 20 drives each LED group 19 with the constant current using the normal current for test (step S101). Next, the test apparatus 20 measure the operating voltage of each LED group 19 (step S102). Next, the test apparatus 20 determines whether all of the differences between the operating voltages are less than the reference value (step S103). The test apparatus 20 goes to step S104 if Yes is determined, and goes to step S105 if No is determined. In the former case, the test apparatus 20 determines that the LED backlight 15 is normal (step S104). In the latter case, the test apparatus 20 determines that the LED backlight 15 is abnormal (step S105). Next, the test apparatus 20 displays the determination result (step S106)

Note that the test apparatus 20 may show the determination result obtained by the backlight test control unit 24 through other methods. For example, the test apparatus 20 may have a green lamp which turns on when the LED backlight 15 is normal and a red lamp which turn on when the LED backlight 15 is abnormal.

Hereinafter, there will be described that the open circuit failure and the short circuit failure of the LED can be detected using the method for testing the LED backlight according to this embodiment. Here, it is assumed that each LED group includes ten LEDs connected in series (q=10) and a forward voltage of the LED is 3 V.

The LEDs are classified into a plurality of ranks based. on various performances (chromaticity, luminous intensity, forward voltage, and the like). The LED groups are configured using LEDs classified into the same rank. Since a width of one rank of the forward voltage is 0.1 to 0.2 V, a maximum difference in the forward voltages of the LEDs included in one LED group is 0.2 V. Therefore, when p=10, a maximum difference between the operating voltages of the normal LED group is 0.2×10=2 V.

When the short circuit failure occurs in the LED, the operating voltage of the LED group is decreased by the forward voltage of the LED. Therefore, when the short circuit failure occurs in a certain LED, the operating voltage of the LED group including the LED is decreased by 3 V. On the other hand, as described above, a maximum value of a variation amount of the operating voltages of the normal LED group is 2 V (when q=10). When the short circuit failure occurs in the LED, the operating voltage of the LED group is decreased greatly than the maximum value of the variation amount of the operating voltages of the normal LED group. Therefore, it is possible to detect the short circuit failure of the LED using the method for testing the LED backlight according to the present embodiment.

Some LEDs include a built-in Zener diode for countermeasures against static electricity, and other LEDs do not include the built-in Zener diode. If the open circuit failure occurs in the LED not including the Zener diode, no current flows through the LED group. Thus, the operating voltage of the LED group becomes theoretically infinite, and becomes a limit value of the voltage in actual. When the open circuit failure occurs in the LED not including the Zener diode, the operating voltage of the LED group is increased more than the maximum value of the variation amount of the operating voltages of the normal LED group. Therefore, it is possible to detect the open circuit failure of the LED not including the Zener diode by using the method for testing the LED backlight according to the present embodiment.

When the open circuit failure occurs in the LED including the Zener diode, a current flows through the LED group, because a reverse current flows through the Zener diode. In this case, an end-to-end voltage of the LED with the failure is equal to a breakdown voltage of the Zener diode (here assumed to be 6 V). Thus, the operating voltage of the LED group is increased by a difference (3 V) between the breakdown voltage of the Zener diode and the forward voltage of the normal LED. When the open circuit failure occurs in the LED including the built-in Zener diode, the operating voltage of the LED group is increased more than the maximum value of the variation amount of the operating voltages of the normal LED group. Therefore, it is possible to detect the open circuit failures of the LED including the Zener diode, by using the method for testing the LED backlight according to the present embodiment.

FIG. 8 is a diagram showing the differences between the operating voltages of the LED groups. In FIG. 8, the differences between the operating voltage of the LED group and the operating voltage of the normal LED group are described, in a case where the LED group includes only normal LEDs, in a case where the LED group includes the LED with the short circuit failure, and in a case where the LED group includes the LED with the open circuit failure. As shown in FIG. 8, when the LED group includes only the normal LEDs, the difference between the operating voltages is close to zero. On the other hand, when the LED group includes the LED with the short circuit failure or the open circuit failure, the difference between the operating voltages is sufficiently larger than zero. There is a difference Vd1 shown in FIG. 8 between the difference between the operating voltages when the LED group includes only the normal LED and the difference of the operating voltages when the LED group includes the LED with the open circuit failure. Therefore, the LED backlight can be tested certainly using the difference

Furthermore, in conventional methods for testing the LED backlight, the plurality of LEDs included in the LED group are tested individually. Therefore, in the conventional methods for testing, it is necessary to provide test terminals connected to each terminal of the LED. In order to test the LED backlight after being incorporated in the liquid crystal display device, it is necessary to use a method for drawing connection wirings from a flexible printed board on which the LEDs are mounted, or a method for providing a hole for inserting a contact probe on a side of the liquid crystal display device.

However, the former method has a problem that implementation is difficult, and the latter method has a problem that foreign matter intrudes from the provided hole. Both methods have a problem that the circuit may be short-circuited due to conductive foreign matter (metal burr, and the like) associated with the terminals, because the terminals are provided on the flexible printed circuit board on which the LEDs are mounted. Thus, it is not realistic to provide the test terminal connected to each terminal of the LED for testing the LED backlight.

On the other hand, in the method for testing the LED backlight according to the present embodiment, it is not necessary to provide a new test terminal, because voltages between existing terminals provided for driving the LED backlight are measured. Therefore, the LED backlight can be tested easily.

As described above, the method for testing the LED backlight according to the present embodiment is a method for testing the LED backlight 15 provided in a display device (liquid crystal display device 10) and having the plurality of LED groups 19 each including the plurality of LEDs 17 connected in series. The method includes steps of driving the LED groups 19a to 19c with the constant current respectively, measuring the operating voltages Vf1 to Vf3 of the LED groups 19a to 19c respectively, determining that the LED backlight 15 is normal when all of the differences between the operating voltages Vf1 to Vf3 are less than the reference value Vdlim1, and determining that the LED backlight 15 is abnormal otherwise.

Furthermore, the test apparatus 20 for the LED backlight according to the present embodiment includes the constant current control unit 22 for driving the LED groups 19a to 19c with the constant current respectively, the voltage measurement unit 23 for measuring the operating voltages Vf1 to Vf3 of the LED groups 19a to 19c respectively, and a determination unit (backlight test control unit 24) for determining that the LED backlight 15 is normal when all of the differences between the operating voltages Vf1 to Vf3 are less than the reference value Vdlim1, and determining that the LED backlight 15 is abnormal otherwise. The plurality of LEDs 17 included in the LED group 19 are connected in series so that the cathode terminal of the LED 17 in the previous stage is connected to the anode terminal of the LED 17 in the next stage.

Therefore, according to the method for testing and the test apparatus of the LED backlight according to the present embodiment, the LED backlight 15 can be tested certainly by measuring the operating voltages of the LED groups 19 and determining whether the LED backlight 15 is normal or abnormal based on the differences between the operating voltages of the LED groups 19a to 19c. Furthermore, since the LED backlight 15 is tested using the existing terminals T0 to T3 provided for driving the LED groups 19a to 19c, the LED backlight 15 can be tested easily without adding test terminals to the LED groups 19a to 19c.

Furthermore, the anode terminals of the LEDs 17 in the first stage included in the LED groups 19a to 19c are connected to a first terminal (terminal T0) common to all of the LED groups 19a to 19c, and the anode terminals of the LEDs 17 in the last stage included in the LED groups 19a to 19c are connected to a second terminal (terminals T1 to T3) provided for each of the LED groups 19a to 19c. In driving with the constant current, the test potential is applied to the first terminal and the potential in accordance with the current flowing through the LED group 19a to 19c is applied to the second terminal. With this, the LED backlight 15 having anode-side terminals of the LED groups 19a to 19c connected to the same terminal can be tested certainly and easily.

Furthermore, in determining, whether all of the differences in the operating voltages Vf1 to Vf3 are less than the reference value Vdlim1 is determined by determining whether the difference between the maximum value Vfmax and the minimum value Vfmin of the operating voltages Vf1 to Vf3 is less than the reference value Vdlim1. Whether all of the differences between the operating voltages are less than the reference value Vdlim1 can be determined easily by comparing the difference between the maximum value Vfmax and the minimum value Vfmin of the operating voltages with the reference value Vdlim1 in this manner.

Furthermore, the display device (liquid crystal display device 10) has the LED backlight 15 and the liquid crystal panel 11, and the LED backlight 15 has a configuration in which the plurality of LEDs 17 are arranged along one or more sides of the light guide plate 18. Therefore, the LED backlight 15 provided in the liquid crystal display device 10 and configured using the plurality of LEDs 17 and the light guide plate 18 can be tested certainly and easily.

### Second Embodiment

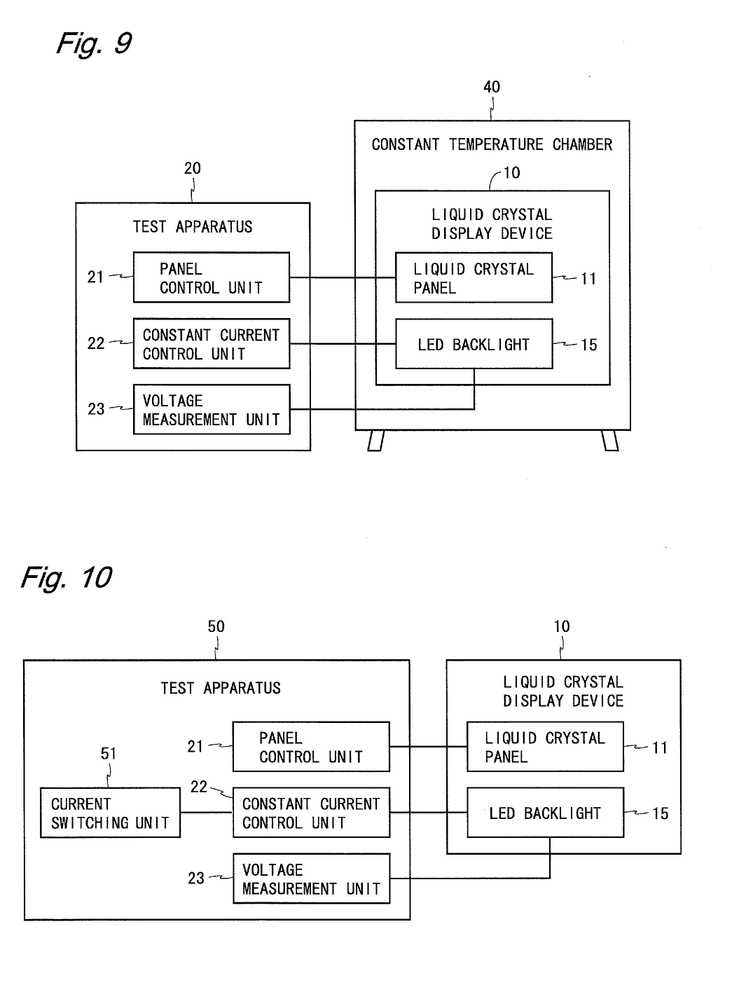

FIG. 9 is a diagram for explaining a method for testing according to a second embodiment of the present invention. As shown in FIG. 9, the method for testing according to the present embodiment is performed in a state where the liquid crystal display device 10 is placed in a constant temperature chamber 40. An inside of the constant temperature chamber 40 is kept at a high temperature state in which the temperature is higher than room temperature. The test apparatus 20 tests the liquid crystal panel 11 and the LED backlight 15 as in the first embodiment, with respect to the liquid crystal display device 10 placed in the high temperature state.

When the liquid crystal display device 10 is placed in the high temperature state, various metal parts included in the liquid crystal display device 10 expand. At this time, a resin portion constituting the LED 17 in the LED backlight 15 also expands, and accordingly stress is generated in a direction to peel off a wire bond wiring. Thus, a loose contact failure of the wire bond wiring occurs easily. Therefore, it is possible to easily detect the loose contact failure of the wire bond wiring, which is difficult to detect at room temperature.

As described above, in the method for testing the LED backlight according to the present embodiment, the display device (liquid crystal display device 10) is placed in the constant temperature chamber 40 whose inside is in the high temperature state. It is possible to easily detect the loose contact failure of the wire bond wiring, which is difficult to detect at room temperature, by testing the LED backlight 15 in the high temperature state.

### Third Embodiment

FIG. 10 is a diagram for explaining a method for testing according to a third embodiment of the present invention. As shown in FIG. 10, in the method for testing according to the present embodiment, a test apparatus 50 is used in place of the test apparatus 20 according to the first embodiment. The test apparatus 50 is obtained by adding a current switching unit 51 to the test apparatus 20 shown in FIG. 5.

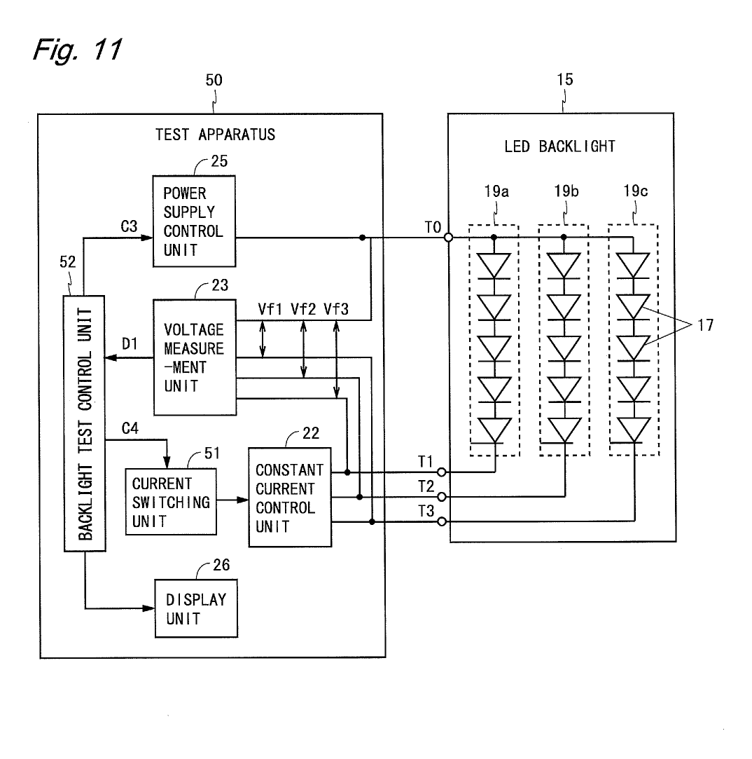

FIG. 11 is a diagram far explaining the method for testing the LED backlight according to the present embodiment. As shown in FIG. 11, the test apparatus 50 includes the constant current control unit 22, the voltage measurement unit 23, the power supply control unit 25, the display unit 26, the current switching unit 51, and a backlight test control unit 52. Hereinafter, among constituent elements of the present embodiment, the same elements as those of the first embodiment are provided with the same reference numerals, and the description thereof will be omitted.

As with the first embodiment, the backlight test control unit 52 outputs, to the power supply control unit 25, the control signal C3 indicating whether to supply the test voltage to the LED backlight 15. In addition, the backlight test control unit 52 outputs, to the current switching unit 51, a control signal C4 indicating whether to use a normal current or a minute current. More specifically, the backlight test control unit 52 first outputs, to the current switching unit 51, the control signal C4 indicating the minute current, and then outputs the control signal C4 indicating the normal current. Based on the control signal C4, the current switching unit 51 switches the amount of current used when the constant current control unit 22 drives the LED group 19 with the constant current. When the control signal C4 indicates the minute current, the constant current control unit 22 controls so that the minute current flows through each LED group 19. When the control signal C4 indicates the normal current, the constant current control unit 22 controls so that the normal current flows through each LED group 19.

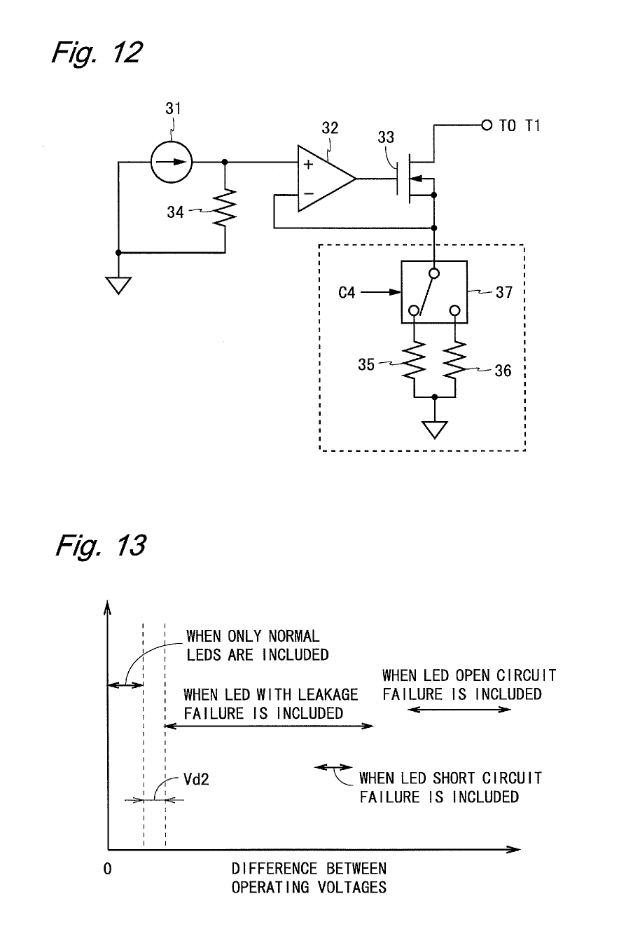

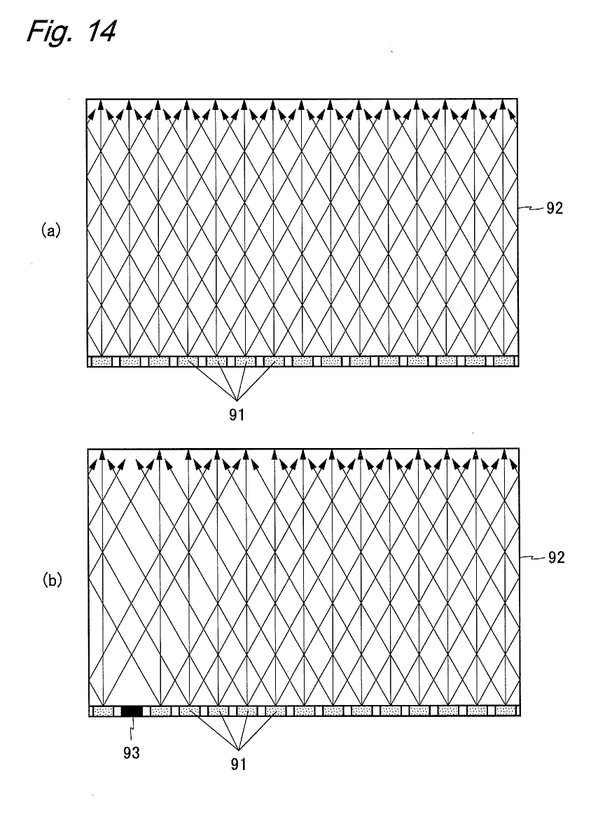

FIG. 12 is a circuit diagram showing a part of the constant current control unit 22 and the current switching unit 51. FIG. 12 shows a circuit corresponding to the LED group 19a. In the circuit shown in FIG. 12, a broken line portion is included in the current switching unit 51, and a remaining portion is included in the constant current control unit 22. In the circuit shown in FIG. 12, the source terminal of the MOSFET 33 is connected to the inverting input terminal of the operational amplifier 32 and a first terminal of a switch 37. A second terminal of the switch 37 is connected to one end of the resistor 35, and a third terminal of the switch 37 is connected to one end of a resistor 36. The other end of the constant current source 31 and the other ends of the resistors 34 to 36 are grounded.

A resistance value of the resistor 35 is determined in accordance with an amount of the normal current, and a resistance value of the resistor 36 is determined in accordance with an amount of the minute current. The resistance value of the resistor 36 is determined to be larger than the resistance value of the resistor 35. For example, when the amount of the minute current is 1/60 of the normal current, the resistance value of the resistor 36 is determined to be 60 times the resistance value of the resistor 35.

As described above, the backlight test control unit 52 first outputs, to the current switching unit 51, the control signal C4 indicating the minute current. At this time, the first terminal and the third terminal of the switch 37 are conducted, a current passing through the MOSFET 33 flows through the resistor 36, and the LED backlight 15 is driven with the minute current. The voltage measurement unit 23 measures the operating voltages Vfa to Vfc of the LED groups 19a to 19c driven with the minute current. In the test apparatus 50, a reference value Vdlim2 of the difference between the operating voltages of the LED groups 19 driven with the minute current is determined in advance. The backlight test control unit 52 determines that the LED backlight 15 does not include the LED 17 with the leakage failure when all of the differences between the operating voltages Vfa to Vfc are less than the reference value Vdlim2, and determines that the LED backlight 15 includes the LED 17 with the leakage failure otherwise.

Next, the backlight test control unit 52 outputs, to the current switching unit 51, the control signal C4 indicating the normal current. At this time, the first terminal and the second terminal of the switch 37 are conducted, the current passing through the MOSFET 33 flows through the resistor 35, and the LED groups 19a to 19c are driven with the normal current. The voltage measurement unit 23 measures the operating voltages Vf1 to Vf3 of the LED groups 19a to 19c driven with the normal current. The backlight test control unit 52 determines that the LED backlight 15 does not include the LED 17 with the open circuit failure or the short circuit failure when all of the differences between the operating voltages Vf1 to Vf3 are less than the reference value Vdlim1, and determines that the LED backlight 15 includes the LED 17 with the open circuit failure or the short circuit failure otherwise.

The backlight test control unit 52 determines that the LED backlight 15 is normal when determining that the LED backlight 15 does not include the LED 17 with the failure by two types of determination described above, and determines that the LED backlight 15 is abnormal otherwise. By testing with the normal current after testing with the minute current in this manner, it is possible to suppress a fluctuation of the operating voltage of the LED 17 due to a heat generation when a former test is performed and reduce an influence of the former test on a latter test.

The display unit 26 displays a screen showing a determination result by the backlight test control unit 52. The display unit 26 may display only whether the LED backlight 15 is normal or abnormal, may display which of the LED groups 19 includes the LED 17 with the failure, or may display a type of an abnormality occurred in the LED 17 (open circuit failure, short circuit failure, or leakage failure).

Hereinafter, there will be described that the leakage failure of the LED can be detected by testing using the minute current included in the method for testing the LED backlight according to the present embodiment. Here, as in the first embodiment, it is assumed that each LED group includes ten LEDs connected in series (q=10) and the forward voltage of the LED is 3 V. Furthermore, it is assumed that the minute current is a current of 1 mA, the forward voltage of the LED when a current of 1 mA flows is 2.5 V, and a maximum value of a variation of the forward voltage is 0.03 V. Furthermore, it is assumed that when the leakage failure occurs in the LED, the forward voltage of the LED when the current of 1 mA flows is 2 V or less.

When the leakage failure occurs in the LED, the operating voltage of the LED group is decreased by 0.5 or more. On the other hand, a maximum difference in the operating voltages of the normal LED group when a current of 1 mA flows is 0.03×10=0.3 V, when q=10.When the leakage failure occurs in the LED, the operating voltage of the LED group is decreased more than the maximum value of the variation amount of the operating voltage of the normal LED group. Therefore, the leakage failure of the LED can be detected by testing with the minute current.

FIG. 13 is a diagram showing the differences between the operating voltages of the LED groups. FIG. 13 is obtained by adding, to FIG. 8, a difference between the operating voltage of the LED group including the LED with the leakage failure and the operating voltage of the normal LED group. There is a difference Vd2 shown in FIG. 13 between the difference between the operating voltages when the LED group includes only the normal LED and the difference in the operating voltages when the LED group includes the LED with the leakage failure. Therefore, the leakage failure of the LED backlight can be tested certainly using the difference Vd2.

As described above, in the method for testing the LED backlight according to the present embodiment, the amount of the drive current used in the constant current drive is switched between the normal current and the minute current. Therefore, it is possible to detect the leakage failure of the LED 17 which can not be detected even when the LED groups 19a to 19c are driven with constant current using the normal current, by driving the LED groups 19a to 19c with the constant current using the minute current.

As described above, according to the method for testing the LED backlight of the present invention, the LED backlight can be tested certainly and easily.

This application is an application claiming priority based on Japanese Patent Application No. 2015-232682 filed on Nov. 30, 2015 entitled “Method for testing LED backlight”, and the content of which is incorporated herein by reference.

### INDUSTRIAL APPLICABILITY

The method for testing an LED backlight of the present invention has a feature that the LED backlight can be tested certainly and easily, so that the method can be used when testing various kinds of LED backlights.

### DESCRIPTION OF REFERENCE CHARACTERS

10: LIQUID CRYSTAL DISPLAY DEVICE

11: LIQUID CRYSTAL PANEL

15: LED BACKLIGHT

17: LED

19: LED GROUP

20, 50: TEST APPARATUS

21: PANEL CONTROL UNIT

22: CONSTANT CURRENT CONTROL UNIT

23: VOLTAGE MEASUREMENT UNIT

24, 52: BACKLIGHT TEST CONTROL UNIT

40: CONSTANT TEMPERATURE CHAMBER

51: CURRENT SWITCHING UNIT

1. A method for testing an LED backlight provided in a display device and having a plurality of LED groups each including a plurality of LEDs connected in series, the method comprising steps of:
driving the LED groups with a constant current respectively;
measuring operating voltages of the LED groups respectively; and
determining that the LED backlight is normal when all of differences between the operating voltages are less than a reference value and determining that the LED backlight is abnormal otherwise.

2. The method for testing according to claim 1, wherein the plurality of LEDs included in the LED group are connected in series so that a cathode terminal of the LED in a previous stage is connected to an anode terminal of the LED in a next stage.

3. The method for testing according to claim 2, wherein
the anode terminal of the LED in a first stage included in the LED group is connected to a first terminal common to all of the LED groups,
the cathode terminal of the LED in a last stage included in the LED group is connected to a second terminal provided for each LED group, and
in driving with the constant current, a test potential is applied to the first terminal and a potential in accordance with a current flowing through the LED group is applied to the second terminal.

4. The method for testing according to claim 3, wherein in determining, whether all of the differences between the operating voltages are less than the reference value is determined by determining whether a difference between a maximum value and a minimum value of the operating voltages is less than the reference value.

5. The method for testing according to claim 1, wherein the display device is placed in a constant temperature chamber whose inside is in a high temperature state.

6. The method for testing according to claim 1, further comprising a step of switching an amount of a drive current used in driving with the constant current, between a normal current and a minute current.

7. The method for testing according to claim 1, wherein the display device has the LED backlight and a liquid crystal panel.

8. The method for testing according to claim 7, wherein the LED backlight has a configuration in which the plurality of LEDs are arranged along one or more sides of a light guide plate.

9. A test apparatus for an LED backlight provided in a display device and having a plurality of LED groups each including a plurality of LEDs connected in series, the apparatus comprising:
a constant current control unit configured to drive the LED groups with a constant current respectively;
a voltage measurement unit configured to measure operating voltages of the LED groups respectively; and
a determination unit configured to determine that the LED backlight is normal when all of differences between the operating voltages are less than a reference value and determine that the LED backlight is abnormal otherwise.
